(19) United States
(12) Patent Application Publication
(10) Pub. No.: US 2024/0429725 A1
(43) Pub. Date: Dec. 26, 2024

(54) Electric Bike Battery Fireproof Charging Station Device

(71) Applicant: Joseph Aronsen, Goshen, NY (US)

(72) Inventor: Joseph Aronsen, Goshen, NY (US)

(21) Appl. No.: 18/657,880

(22) Filed: May 8, 2024

Related U.S. Application Data
(60) Provisional application No. 63/509,576, filed on Jun. 22, 2023.

(51) Int. Cl. H02J 7/00; A62C 3/16; H02H 5/00; H05K 5/02; H05K 7/20

(52) U.S. Cl. CPC H02J 7/0045; A62C 3/16; H02H 5/00; H05K 5/0209; H05K 5/0221; H05K 5/023; H05K 7/20136

(57) ABSTRACT

A fireproof charging station device is disclosed to prevent fires caused by electric bike, skateboard, and hoverboard batteries in apartments, homes, and garages. The fireproof charging station device comprises a body component that is configured to retain at least one battery, hooked up to a charger. The body component comprises a lid and a handle for easy transport. Further, the body component comprises a smoke sensor used to detect any immediate smoke and in turn will cut any power being actively supplied from the charger to the battery within the body component. The body component also comprises a fire suppressant canister system that comprises sensors to detect extreme heat or flames, then will smother the battery with fire suppressant if a flame is detected inside the body component.

### CROSS-REFERENCE TO RELATED APPLICATION

The present application claims priority to, and the benefit of, U.S. Provisional Application No. 63/509,576, which was filed on Jun. 22, 2023, and is incorporated herein by reference in its entirety.

### FIELD OF THE INVENTION

The present invention relates generally to the field of fireproof charging station devices. More specifically, the present invention relates to a mountable fireproof box for charging electric bike, skateboard, and hoverboard batteries. Accordingly, the present disclosure makes specific reference thereto. Nonetheless, it is to be appreciated that aspects of the present invention are also equally applicable to other like applications, devices, and methods of manufacture.

### BACKGROUND

By way of background, this invention relates to improvements in fireproof charging station devices. Generally, people who own skateboards, electric bikes, and hoverboards may lack proper areas to charge their batteries. Thus, the batteries may be placed on the floor or a table and be at risk for starting a fire. Furthermore, house fires can cause loss of life and significant property damage that can be expensive to replace.

Additionally, rechargeable batteries in almost any device can malfunction and ignite while the device is being recharged, causing a significant risk of injury to users as the likelihood of homes burning down and family members dying in fires is very real. Therefore, a need exists for a new and novel solution to prevent electronic device battery fire from igniting the area around it while it is charging.

Accordingly, there is a demand for an improved fireproof charging station device that allows users to safely charge their batteries without worry of fires starting. More particularly, there is a demand for a fireproof charging station device that prevents fires caused by charging batteries in apartments, homes, and garages.

Therefore, there exists a long-felt need in the art for a fireproof charging station device that provides users with a mountable fireproof box for charging electric bike, skateboard, and hoverboard batteries. There is also a long-felt need in the art for a fireproof charging station device that allows users to safely charge their vehicle batteries in apartments, homes, and garages without worry of fires starting. Further, there is a long-felt need in the art for a fireproof charging station device that includes a smoke-detecting device within the box that can identify smoke and cut any power to the charger. Moreover, there is a long-felt need in the art for a device that offers an optional fire suppressant canister system that can smother the battery if a flame is detected. Further, there is a long-felt need in the art for a fireproof charging station device that improves safety when charging electric bike, skateboard, and hoverboard batteries. Finally, there is a long-felt need in the art for a fireproof charging station device that comprises a carrying handle.

The subject matter disclosed and claimed herein, in one embodiment thereof, comprises a fireproof charging station device. The device prevents fires caused by electric bike, skateboard, and hoverboard batteries in apartments, homes, and garages. The fireproof charging station device comprises a body component that is configured in a square or rectangular shape that will look like a fireproof box or a cooler to hold at least one battery. At least one battery is placed within the body component before hooking the battery up to the charger. The body component comprises a lid and a handle for easy transport. Further, the body component comprises a smoke sensor used to detect any immediate smoke and in turn will cut any power being actively supplied from the charger to the battery within the body component. The body component also comprises a foam canister system that comprises sensors to detect extreme heat or flames, then will smother the battery with fire suppressant if a flame is detected inside the body component.

In this manner, the fireproof charging station device of the present invention accomplishes all of the foregoing objectives and provides users with a device that safely charges batteries without worrying of fires. The device is a fireproof box with additional sensors. The device can be mounted to a wall or left on the floor.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a fireproof charging station device. The device prevents fires caused by electric bike, skateboard, and hoverboard batteries in apartments, homes, and garages. The fireproof charging station device comprises a body component that is configured in a square or rectangular shape that will look like a fireproof box or a cooler to hold at least one battery. At least one battery is placed within the body component before hooking the battery up to the charger. The body component comprises a lid and a handle for easy transport. Further, the body component comprises a smoke sensor used to detect any immediate smoke and in turn will cut any power being actively supplied from the charger to the battery within the body component. The body component also comprises a fire suppressant canister system that comprises sensors to detect extreme heat or flames, then will smother the battery with fire suppressant if a flame is detected inside the body component.

In one embodiment, the fireproof charging station device is a robust container intended to safely store and charge lithium-ion batteries and other suitable batteries. The device also provides automatic fire suppression to prevent the propagation of cell-to-cell fires and other heat and energy related destructive events. The device is also applicable to other types of batteries or electronics that have a tendency to overheat and catch fire.

In one embodiment, the fireproof charging station device comprises a body component that is a fire-retardant enclosure. The body component is comprised of fire-retardant material that can resist temperatures of at least 1000 degrees Celsius. The fire-retardant material could be a fabric that is inherently fire-retardant, such as, but not limited to, tightly woven wool (such as kaowool), or polyesters. The fire-retardant material could also be fabrics that are chemically treated to be fire-retardant by any means known in the field such as Polybrominated diphenyl ethers (PBDE). Further, lightweight materials can also be used, such as carbon foam, carbon/carbonized fiber, Kevlar, silicone infused fiberglass products, ceramic tiles, PVC/fiberglass material, and other comparable materials are contemplated by this disclosure. Additionally, the body component comprises a bottom, opposing sidewalls, opposing front and back walls, and an open top allowing access to the interior of the body component.

In one embodiment, the open top is closed via a lid. The lid seals the body component to ensure it is fire-retardant. Further, the lid comprises a latch, to secure the lid to the body component. Other configurations for securing the lid, including, but not limited to, Velcro or a zipper are contemplated by this disclosure.

In one embodiment, the lid is attached to one end of the open top via hinges, though any attachment means that allows for the opening and closing of the lid is contemplated by this disclosure including a top closure that is not permanently connected and is just placed on the body component to form the enclosure.

In one embodiment, the batteries are not only stored in the body component but may also be charged. Therefore, each body component also includes a charger connector/port therein for connecting to battery leads to charge the battery or batteries while they are stored in the body component. The charge connector is part of any known charging arrangement including a power source, a circuit/wire, and controls to provide the most efficient charging current to the battery. In this embodiment, a charge connector/port with circuit/wire extends through the body component to connect to the battery and is capable of connecting to an external power source located outside of the body component. Typically, the charge connector/port is positioned in what is typically considered the back of the body component, though any feasible position of the charge connector/port with a circuit/wire extending through the body component to an external power source is contemplated by this disclosure.

In one embodiment, the body component comprises a charge connector/port positioned external the body component and able to be accessed by the battery within the body component. The charge connector/port would be connected to an electrical outlet which provides power to charge the battery enclosed in the fireproof structure. Specifically, a wire (electrical cord) connects to the power source (i.e., electrical outlet) and transfers an electrical charge to the charge connector/port. Alternatively, this disclosure also contemplates the charge connector/port connecting with wireless connectivity to power the battery. The user would place the battery inside of the body component, plug the battery into the charge connector/port, and then close and secure the lid on the body component.

In one embodiment, an electric eye smoke sensor is fixedly disposed on an interior side of the body component. The electric eye smoke sensor is used to detect any immediate smoke and in turn, if smoke is detected, will cut any power being actively supplied from the charge connector/port to the battery within the body component. Thus, the electric eye smoke sensor identifies and detects smoke within the body component and cuts any power to the charge connector/port when smoke is detected. Accordingly, in the event that smoke is detected, an electric eye smoke sensor will cut power to a power source.

In one embodiment, the electric eye smoke sensor for sensing smoke within the body component is positioned at the top portion/ceiling of the body component. The positioning of the sensor at the ceiling is optimal at the ceiling, however, the sensor may alternatively positioned at other locations within the body component. The sensor may be a known sensor such as a photoelectric or an ionization detector that detects fire and smoke. Photoelectric detectors would detect the difference in the transmission of light due to smoke or fire. Ionization detectors would detect the presence of hydrocarbons created by combustion. It is within the scope of this invention that the sensor combines both photoelectric and ionization technologies in one device.

In one embodiment, a fire suppressant canister device can be fixedly disposed on an exterior of the body component with the nozzle of the fire suppressant canister device having access to the interior of the body component. Thus, if extreme heat and/or flame is detected inside the body component, then the fire suppressant canister device is activated and fire suppressant is released through the nozzle to smother the battery. Accordingly, in the event that a certain level of heat and/or flame is detected, the fire suppressant canister device is activated and fire suppressant is released through the nozzle, which will fill the interior of the body component to smother and extinguish the flames.

In one embodiment, a cooling fan is fixedly mounted on an interior surface, to cool the interior of the body component, as needed.

In one embodiment, a temperature sensor is fixedly mounted to an interior surface of the body component. The temperature within the body component can then be sensed and, when the temperature rises to a certain numerical value, the fire suppressant canister device is activated to smother the battery with fire suppressant. After the temperature sensor transmits a signal to the cooling fan, the cooling fan will normally operate, and if the temperature of the interior of the body component continues to rise above the warning value set by the temperature sensor, the possibility of fire/flames on the battery increases, and the temperature sensor will then transmit an electric signal to the fire suppressant canister device to spray fire suppressant on the battery, to prevent fire. Thus, the arrangement can effectively protect the battery and can extinguish the fire quickly even after the fire occurs, thereby minimizing the damage to the battery.

In one embodiment, an alarm is fixedly installed on a surface of the body component, and the alarm is electrically connected with the temperature sensor. If a high level of temperature is detected, the alarm is sounded, alerting a user to the heat and/or flames present in the body component.

In one embodiment, the body component comprises a power supply. The power supply supplies power to the plurality of sensors, and to each of the charging circuits which are used to charge batteries stored therein. The sensors communicate with the power supply to disrupt power to the charging battery in the event of fire events.

In one embodiment, the body component comprises at least one observation window. Then at least one observation window is made from insulating glass that provides transparency, to determine the state of the battery inside the body component.

In one embodiment, the body component is mounted on a wall or positioned on the floor for use. If mounted on the wall, any suitable securing means can be used, such as nails, bolts, screws, adhesives, etc. If positioned on the floor, the body component can be positioned directly on the floor or positioned on a countertop or other suitable surface a specific distance from the floor.

In one embodiment, the body component comprises a carrying handle. The handle can be secured to the lid or to either side of the body component. The handle can be manufactured of any suitable material, such as nylon, rubber, plastic, etc. The handle can be any suitable size as is known in the art, as long as the handle allows a user to easily transport the device, as needed.

In yet another embodiment, the fireproof charging station device comprises a plurality of indicia.

In yet another embodiment, a method of safely charging skateboard, electric bike, and hoverboard batteries is disclosed. The method includes the steps of providing a fireproof charging station device comprising a body component for retaining a battery. The method also comprises inserting a battery into the body component and hooking up a charger to the battery. Further, the method comprises securing the lid to the body component. The method also comprises detecting smoke, then the smoke sensor will cut any power being actively supplied from the charger to the battery within the body component. Further, the method comprises detecting a flame, then the fire suppressant canister system will emit fire suppressant to smother the battery and flame. Finally, the method comprises finished charging, then removing the battery from the body component for use.

Numerous benefits and advantages of this invention will become apparent to those skilled in the art to which it pertains, upon reading and understanding the following detailed specification.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of one embodiment of the fireproof charging station device of the present invention showing the device charging a battery in accordance with the disclosed architecture;

FIG. 2 illustrates a perspective view of one embodiment of the fireproof charging station device of the present invention showing how the lid is secured to the device and the device is on the floor in accordance with the disclosed architecture;

FIG. 3 illustrates a perspective view of one embodiment of the fireproof charging station device of the present invention showing the handle of the device in accordance with the disclosed architecture;

FIG. 4 illustrates a perspective view of one embodiment of the fireproof charging station device of the present invention showing the device mounted on a wall in accordance with the disclosed architecture;

FIG. 5 illustrates a perspective view of one embodiment of the fireproof charging station device of the present invention in use in accordance with the disclosed architecture; and

FIG. 6 illustrates a flowchart showing the method of safely charging skateboard, electric bike, and hoverboard batteries in accordance with the disclosed architecture.

### DETAILED DESCRIPTION OF THE PRESENT INVENTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there is a long-felt need in the art for a fireproof charging station device that provides users with a mountable fireproof box for charging electric bike, skateboard, and hoverboard batteries. There is also a long-felt need in the art for a fireproof charging station device that allows users to safely charge their vehicle batteries in apartments, homes, and garages without worry of fires starting. Further, there is a long-felt need in the art for a fireproof charging station device that includes a smoke-detecting device within the box that can identify smoke and cut any power to the charger. Moreover, there is a long-felt need in the art for a device that offers an optional fire suppressant canister system that can smother the battery if a flame is detected. Further, there is a long-felt need in the art for a fireproof charging station device that improves safety when charging electric bike, skateboard, and hoverboard batteries. Finally, there is a long-felt need in the art for a fireproof charging station device that comprises a carrying handle.

The present invention, in one exemplary embodiment, is a novel fireproof charging station device. The device prevents fires caused by electric bike, skateboard, and hoverboard batteries in apartments, homes, and garages. The fireproof charging station device comprises a body component that is configured to retain at least one battery, which is hooked up to the charger. The body component comprises a lid and a handle for easy transport. Further, the body component comprises a smoke sensor used to detect any immediate smoke and in turn will cut any power being actively supplied from the charger to the battery within the body component. The body component also comprises a fire suppressant canister system that comprises sensors to detect extreme heat or flames, then will smother the battery with fire suppressant if a flame is detected inside the body component. The present invention also includes a novel method of safely charging skateboard, electric bike, and hoverboard batteries. The method includes the steps of providing a fireproof charging station device comprising a body component for retaining a battery. The method also comprises inserting a battery into the body component and hooking up a charger to the battery. Further, the method comprises securing the lid to the body component. The method also comprises detecting smoke, then the smoke sensor will cut any power being actively supplied from the charger to the battery within the body component. Further, the method comprises detecting a flame, then the fire suppressant canister system will emit fire suppressant to smother the battery and flame. Finally, the method comprises finished charging, then removing the battery from the body component for use.

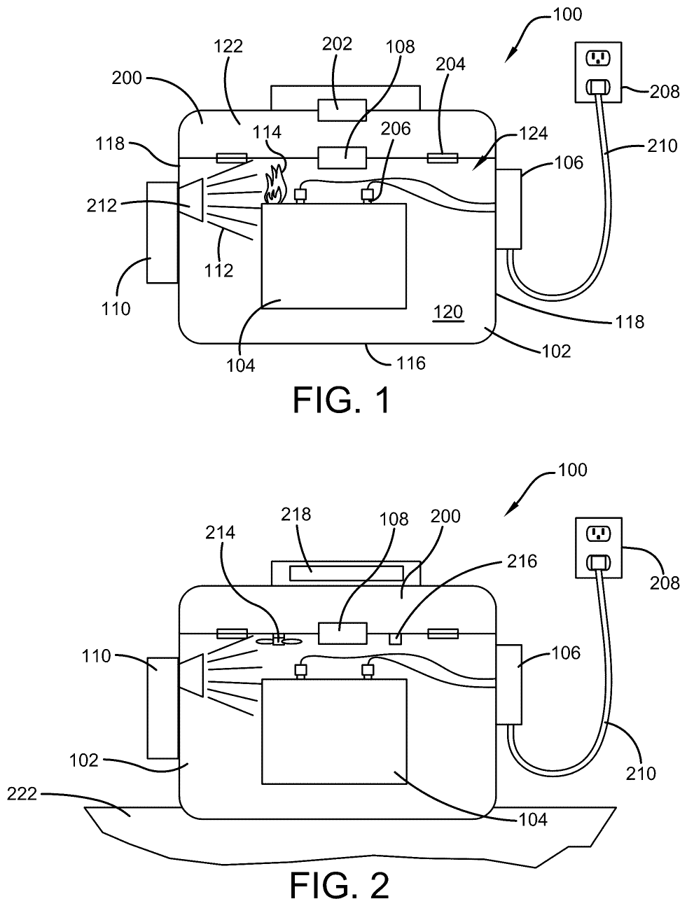

Referring initially to the drawings, FIG. 1 illustrates a perspective view of one embodiment of the fireproof charging station device 100 of the present invention. In the present embodiment, the fireproof charging station device 100 is an improved fireproof charging station device 100 that provides a user with a means to safely charge the electric bike, skateboard, and hoverboard batteries in apartments, homes, and garages. Specifically, the fireproof charging station device 100 comprises a body component 102 that is configured in a square or rectangular shape that will look like a fireproof box or a cooler to hold at least one battery 104. At least one battery 104 is placed within the body component 102 before hooking the battery 104 up to the charge connector/port 106. Further, the body component 102 comprises a smoke sensor 108 used to detect any immediate smoke and in turn will cut any power being actively supplied from the charge connector/port 106 to the battery 104 within the body component 102. The body component 102 also comprises a fire suppressant canister device 110 that comprises sensors to detect extreme heat or flames, then will smother the battery 104 with fire suppressant 112 if a flame 114 is detected inside the body component 102.

Generally, the fireproof charging station device 100 is a robust container intended to safely store and charge lithium-ion batteries 104 and other suitable batteries. The device 100 also provides automatic fire suppression to prevent the propagation of cell-to-cell fires and other heat and energy related destructive events. The device 100 is also applicable to other types of batteries 104 or electronics that have a tendency to overheat and catch fire.

Furthermore, the fireproof charging station device 100 comprises a body component 102 that is a fire-retardant enclosure. The body component 102 is comprised of fire-retardant material that can resist temperatures of at least 1000 degrees Celsius. The fire-retardant material could be a fabric that is inherently fire-retardant, such as, but not limited to, tightly woven wool (such as kaowool), or polyesters. The fire-retardant material could also be fabrics that are chemically treated to be fire-retardant by any means known in the field such as Polybrominated diphenyl ethers (PBDE). Further, lightweight materials can also be used, such as carbon foam, carbon/carbonized fiber, Kevlar, silicone infused fiberglass products, ceramic tiles, PVC/fiberglass material, and other comparable materials are contemplated by this disclosure. Additionally, the body component 102 comprises a bottom 116, opposing sidewalls 118, opposing front and back walls 120, and an open top 122 allowing access to the interior 124 of the body component 102.

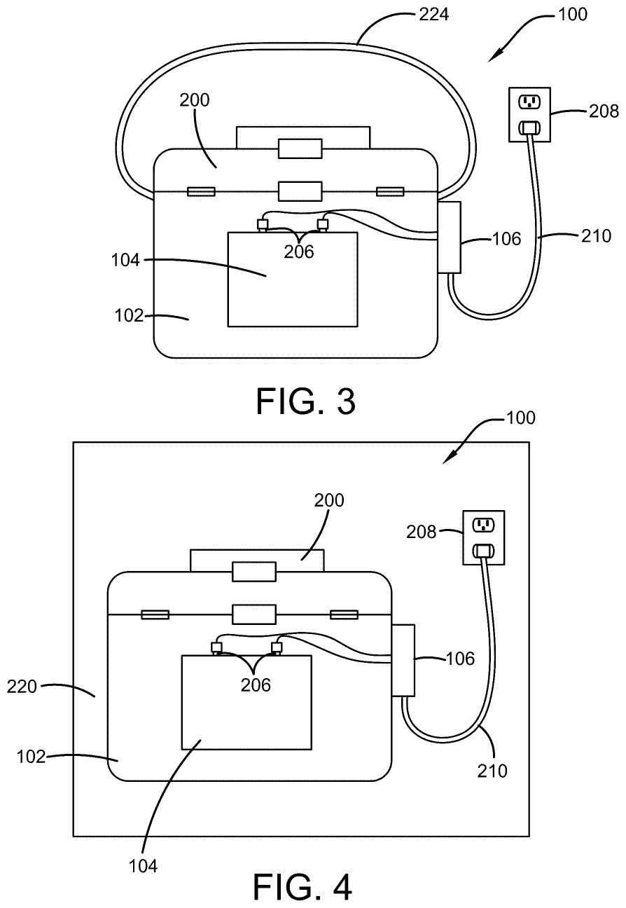

As shown in FIGS. 2-4, the open top 122 is closed via a lid 200. The lid 200 seals the body component 102 to ensure it is fire-retardant. Further, the lid 200 comprises a latch 202, to secure the lid 200 to the body component 102. Other configurations for securing the lid 200, including, but not limited to, Velcro or a zipper are contemplated by this disclosure.

Furthermore, the lid 200 is attached to one end of the open top 122 via hinges 204, though any attachment means that allows for the opening and closing of the lid 200 is contemplated by this disclosure including a top closure that is not permanently connected and is just placed on the body component 102 to form the enclosure.

Additionally, the batteries 104 are not only stored in the body component 102 but may also be charged. Therefore, each body component 102 also includes a charger connector/port 106 therein for connecting to battery leads 206 to charge the battery 104 or batteries while they are stored in the body component 102. The charge connector 106 is part of any known charging arrangement including a power source 208, a circuit/wire 210, and controls to provide the most efficient charging current to the battery 104. Typically, a charge connector/port 106 with circuit/wire 210 extends through the body component 102 to connect to the battery 104 and is capable of connecting to an external power source 208 located outside of the body component 102. Typically, the charge connector/port 106 is positioned in what is typically considered the back of the body component 102, though any feasible position of the charge connector/port 106 with a circuit/wire 210 extending through the body component 102 to an external power source 208 is contemplated by this disclosure.

Furthermore, the body component 102 comprises a charge connector/port 106 positioned external the body component 102 and able to be accessed by the battery 104 within the body component 102. The charge connector/port 106 would be connected to an electrical outlet 208 which provides power to charge the battery 104 enclosed in the fireproof structure. Specifically, a wire 210 (electrical cord) connects to the power source 208 (i.e., electrical outlet) and transfers an electrical charge to the charge connector/port 106. Alternatively, this disclosure also contemplates the charge connector/port 106 connecting with wireless connectivity to power the battery 104. The user would place the battery 104 inside of the body component 102, plug the battery 104 into the charge connector/port 106, and then close and secure the lid 200 on the body component 102.

Additionally, an electric eye smoke sensor 108 is fixedly disposed on an interior side of the body component 102. The electric eye smoke sensor 108 is used to detect any immediate smoke and in turn, if smoke is detected, will cut any power being actively supplied from the charge connector/port 106 to the battery 104 within the body component 102. Thus, the electric eye smoke sensor 108 identifies and detects smoke within the body component 102 and cuts any power to the charge connector/port 106 when smoke is detected. Accordingly, in the event that smoke is detected, electric eye smoke sensor 108 will cut power to power source 208.

Further, the electric eye smoke sensor 108 for sensing smoke within the body component 102 is positioned at the top portion/ceiling of the body component 102. The positioning of the sensor 108 at the ceiling is optimal at the ceiling, however, the sensor 108 may alternatively positioned at other locations within the body component 102. The sensor 108 may be a known sensor such as a photoelectric or an ionization detector that detects fire and smoke. Photoelectric detectors would detect the difference in the transmission of light due to smoke or fire. Ionization detectors would detect the presence of hydrocarbons created by combustion. It is within the scope of this invention that the sensor 108 combines both photoelectric and ionization technologies in one device.

Additionally, a fire suppressant canister device 110 can be fixedly disposed on an exterior of the body component 102 with the nozzle 212 of the fire suppressant canister device 110 having access to the interior of the body component 102. Thus, if extreme heat and/or flame is detected inside the body component 102, then the fire suppressant canister device 110 is activated and fire suppressant 112 is released through the nozzle 212 to smother the battery 104. Accordingly, in the event that a certain level of heat and/or flame 114 is detected, the fire suppressant canister device 100 is activated and fire suppressant 112 is released through the nozzle 212, which will fill the interior of the body component 102 to smother and extinguish the flames 114.

In one embodiment, a cooling fan 214 is fixedly mounted on an interior surface, to cool the interior of the body component 102, as needed.

In one embodiment, a temperature sensor 216 is fixedly mounted to an interior surface of the body component 102. The temperature within the body component 102 can then be sensed and, when the temperature rises to a certain numerical value, the fire suppressant canister device 110 is activated to smother the battery 104 with fire suppressant 112. After the temperature sensor 216 transmits a signal to the cooling fan 214, the cooling fan 214 will normally operate, and if the temperature of the interior of the body component 102 continues to rise above the warning value set by the temperature sensor 216, the possibility of fire/flames 114 on the battery 104 increases, and the temperature sensor 216 will then transmit an electric signal to the fire suppressant canister device 110 to spray fire suppressant 112 on the battery 104, to prevent fire. Thus, the arrangement can effectively protect the battery 104 and can extinguish the fire quickly even after the fire occurs, thereby minimizing the damage to the battery 104.

In one embodiment, an alarm 218 is fixedly installed on a surface of the body component 102, and the alarm 218 is electrically connected with the temperature sensor 216. If a high level of temperature is detected, the alarm 218 is sounded, alerting a user to the heat and/or flames 114 present in the body component 102.

Generally, the body component 102 comprises a power supply. The power supply supplies power to the plurality of sensors, and to each of the charging circuits which are used to charge batteries 104 stored therein. The sensors communicate with the power supply to disrupt power to the charging battery 104 in the event of fire events.

Furthermore, the body component 102 is mounted on a wall 220 or positioned on the floor 222 for use. If mounted on the wall 220, any suitable securing means can be used, such as nails, bolts, screws, adhesives, etc. If positioned on the floor 222, the body component 102 can be positioned directly on the floor 222 or positioned on a countertop or other suitable surface a specific distance from the floor 222.

In one embodiment, the body component 102 comprises a carrying handle 224. The handle 224 can be secured to the lid 200 or to either side of the body component 102. The handle 224 can be manufactured of any suitable material, such as nylon, rubber, plastic, etc. The handle 224 can be any suitable size as is known in the art, as long as the handle 224 allows a user to easily transport the device 100, as needed.

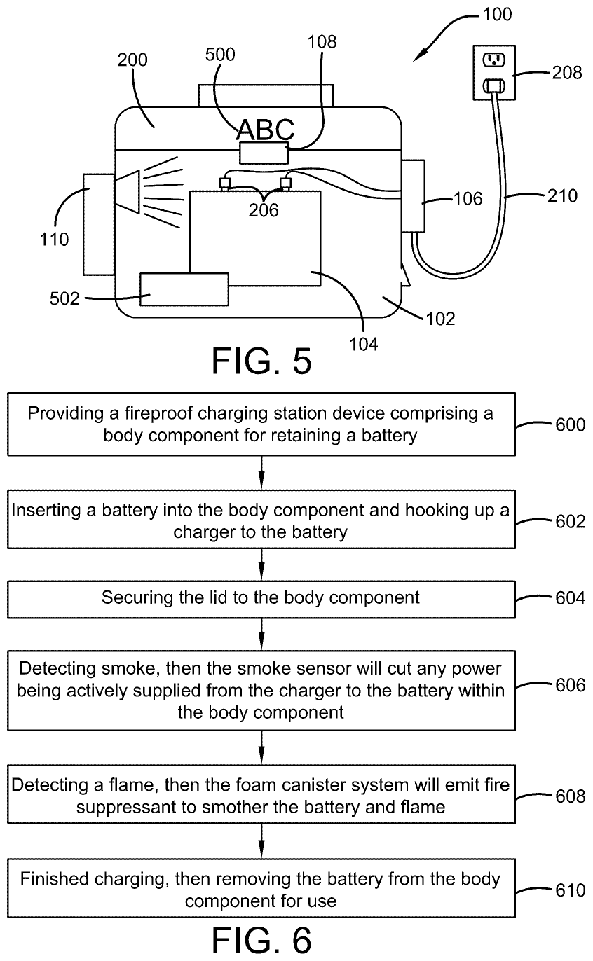

As shown in FIG. 5, the body component 102 comprises at least one observation window 502. Then at least one observation window 502 is made from insulating glass that provides transparency, to determine the state of the battery 104 inside the body component 102.

In yet another embodiment, the fireproof charging station device 100 comprises a plurality of indicia 500. The body component 102 of the device 100 may include advertising, a trademark, or other letters, designs, or characters, printed, painted, stamped, or integrated into the body component 102, or any other indicia 500 as is known in the art. Specifically, any suitable indicia 500 as is known in the art can be included, such as, but not limited to, patterns, logos, emblems, images, symbols, designs, letters, words, characters, animals, advertisements, brands, etc., that may or may not be battery, charging, or brand related.

FIG. 6 illustrates a flowchart of the method of safely charging skateboard, electric bike, and hoverboard batteries. The method includes the steps of at 600, providing a fireproof charging station device comprising a body component for retaining a battery. The method also comprises at 602, inserting a battery into the body component and hooking up a charger to the battery. Further, the method comprises at 604, securing the lid to the body component. The method also comprises at 606, detecting smoke, then the smoke sensor will cut any power being actively supplied from the charger to the battery within the body component. Further, the method comprises at 608, detecting a flame, then the fire suppressant canister system will emit fire suppressant to smother the battery and flame. Finally, the method comprises at 610, finished charging, then removing the battery from the body component for use.

Certain terms are used throughout the following description and claims to refer to particular features or components. As one skilled in the art will appreciate, different users may refer to the same feature or component by different names. This document does not intend to distinguish between components or features that differ in name but not structure or function. As used herein “fireproof charging station device”, “charging station device”, “fireproof device”, and “device” are interchangeable and refer to the fireproof charging station device 100 of the present invention.

Notwithstanding the foregoing, the fireproof charging station device 100 of the present invention can be of any suitable size and configuration as is known in the art without affecting the overall concept of the invention, provided that it accomplishes the above-stated objectives. One of ordinary skill in the art will appreciate that the fireproof charging station device 100 as shown in FIGS. 1-6 is for illustrative purposes only, and that many other sizes and shapes of the fireproof charging station device 100 are well within the scope of the present disclosure. Although the dimensions of the fireproof charging station device 100 are important design parameters for user convenience, the fireproof charging station device 100 may be of any size that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A fireproof charging station device that provides a user with a means to safely charge electric bike, skateboard, and hoverboard batteries, the fireproof charging station device comprising:
a body component; and
a lid;
wherein the body component is configured to house a battery to be charged;
wherein the lid encloses the body component;
wherein the battery within the body component is connected to a charge connector to charge the battery; and
further wherein the body component is fireproof to protect the battery while it is charged.

2. The fireproof charging station device of claim 1, wherein the body component is a fire-retardant enclosure.

3. The fireproof charging station device of claim 2, wherein the body component comprises a bottom, opposing sidewalls, opposing front and back walls, and an open top allowing access to an interior of the body component.

4. The fireproof charging station device of claim 3, wherein the open top is closed via the lid with a latch.

5. The fireproof charging station device of claim 4, wherein the lid is attached to one end of the open top via hinges.

6. The fireproof charging station device of claim 5, wherein the charger connector is connected to battery leads to charge the battery.

7. The fireproof charging station device of claim 6, wherein the charge connector with wire extends through the body component to connect to the battery and is capable of connecting to an external power source located outside of the body component.

8. The fireproof charging station device of claim 7, wherein the charge connector connects with wireless connectivity to power the battery.

9. The fireproof charging station device of claim 8, wherein the body component comprises a smoke sensor fixedly disposed on an interior side of the body component, which is used to detect any immediate smoke and in turn, if smoke is detected, will cut any power being actively supplied from the charge connector to the battery within the body component.

10. The fireproof charging station device of claim 9, wherein the body component comprises a fire suppressant canister device fixedly disposed on an exterior of the body component with a nozzle of the fire suppressant canister device having access to the interior of the body component.

11. The fireproof charging station device of claim 10, wherein if extreme heat or flame is detected inside the body component, then the fire suppressant canister device is activated and fire suppressant is released through the nozzle to smother the battery.

12. The fireproof charging station device of claim 11, wherein the body component is mounted on a wall or positioned on a floor during use.

13. A fireproof charging station device that provides a user with a means to safely charge electric bike, skateboard, and hoverboard batteries, the fireproof charging station device comprising:
a body component which is a fire-retardant enclosure that comprises a bottom, opposing sidewalls, opposing front and back walls, and an open top allowing access to an interior of the body component; and
a lid with a latch to close the open top;
wherein the body component is configured to house a battery to be charged;
wherein the lid encloses the body component and is attached to one end of the open top via hinges;
wherein the battery within the body component is connected to a charge connector via battery leads to charge the battery;
wherein the charge connector with wire extends through the body component to connect to the battery and is capable of connecting to an external power source located outside of the body component;
wherein the charge connector connects with wireless connectivity to power the battery;
wherein the body component comprises a smoke sensor fixedly disposed on an interior side of the body component, which is used to detect any immediate smoke and in turn, if smoke is detected, will cut any power being actively supplied from the charge connector to the battery within the body component;
wherein the body component comprises a fire suppressant canister device fixedly disposed on an exterior of the body component with a nozzle of the fire suppressant canister device having access to the interior of the body component;
wherein if extreme heat or flame is detected inside the body component, then the fire suppressant canister device is activated and fire suppressant is released through the nozzle to smother the battery; and
further wherein the body component is mounted on a wall or positioned on a floor during use.

14. The fireproof charging station device of claim 13 further comprising a cooling fan fixedly mounted on an interior surface of the body component.

15. The fireproof charging station device of claim 13 further comprising a temperature sensor fixedly mounted to an interior surface of the body component, wherein when a sensed temperature rises to a certain numerical value, the fire suppressant canister device is activated to smother the battery with fire suppressant.

16. The fireproof charging station device of claim 13 further comprising an alarm fixedly installed on a surface of the body component, and the alarm is electrically connected with the temperature sensor to sound if a high level of temperature is detected within the body component.

17. The fireproof charging station device of claim 13 further comprising a carrying handle for transport.

18. The fireproof charging station device of claim 13 further comprising at least one observation window on the body component to determine state of the battery inside the body component.

19. The fireproof charging station device of claim 13 further comprising a plurality of indicia.

20. A method of safely charging skateboard, electric bike, and hoverboard batteries, the method comprising the following steps:
providing a fireproof charging station device comprising a body component for retaining a battery;
inserting a battery into the body component and hooking up a charger to the battery; securing the lid to the body component;
detecting smoke, then the smoke sensor will cut any power being actively supplied from the charger to the battery within the body component;
detecting a flame, then the fire suppressant canister system will emit fire suppressant to smother the battery and flame; and
finished charging, then removing the battery from the body component for use.
